(19) United States
(12) Patent Application Publication
(10) Pub. No.: US 2026/0190492 A1
(43) Pub. Date: Jul. 2, 2026

(54) DISPLAY SUBSTRATE AND DISPLAY DEVICE

(71) Applicant: BOE TECHNOLOGY GROUP CO., LTD., Beijing (CN)

(72) Inventors: Wei YANG, Beijing (CN); Guangcai YUAN, Beijing (CN); Ce NING, Beijing (CN); Dongni LIU, Beijing (CN); Lizhong WANG, Beijing (CN); Binbin TONG, Beijing (CN); Zhen ZHANG, Beijing (CN)

(73) Assignee: BOE TECHNOLOGY GROUP CO., LTD., Beijing (CN)

(21) Appl. No.: 18/842,527

(22) PCT Filed: Oct. 17, 2023
(86) PCT No.: PCT/CN2023/124881

§ 371 Date: Aug. 29, 2024

(51) Int. Cl. H10D 86/40; H10D 86/60

(52) U.S. Cl. CPC H10D 86/481; H10D 86/421; H10D 86/60

(57) ABSTRACT

A display substrate and a display device. The display substrate includes a base substrate, and at least three functional layers, at least two first adaptation layers and a target connection member arranged on the base substrate. At least two functional layers of the at least three functional layers are laminated one on another in a direction away from the base substrate, and the at least three functional layers include a target functional layer. The at least two first adaptation layers include a top adaptation layer and at least one bottom adaptation layer, the top adaptation layer is arranged at a side of the target functional layer away from the base substrate, and at least a part of the bottom adaptation layer is arranged between the target functional layer and the base substrate.

### TECHNICAL FIELD

The present disclosure relates to the field of display technology, in particular to a display substrate and a display device.

### BACKGROUND

In recent years, along with an increase in a pixel density of a display product, e.g., an Augmented Reality (AR) or Virtual Reality (VR) product, an area of a single pixel becomes smaller and smaller, which imposes higher and higher requirements on a layout design and a process capability. In particular, for some complex processes such as Low Temperature Polycrystalline Oxide (LTPO) process or stacked thin film transistor process, in the layout design, due to a smaller area of a single pixel, on one hand, a space for metal lines is reduced, so short circuit may easily occur and thereby a resolution of the product may be adversely affected. On the other hand, metal layers are coupled to each other, or a metal layer is coupled to an active layer, or active layers are electrically coupled to each other through a plurality of through holes. Tue to an increase in the quantity of through holes, a width of a metal line through which the through holes are coupled increases, and thereby the resolution of the display product may be further adversely affected. Hence, there is an urgent need to optimize the layout design and the process, so as to reduce the density of the metal lines or reduce the quantity of through holes, thereby to improve the resolution of the display product.

### SUMMARY

An object of the present disclosure is to provide a display substrate and a display device, so as to solve the problems in the related art.

In order to achieve the above-mentioned object, the present disclosure provides the following technical solutions.

In one aspect, the present disclosure provides in some embodiments a display substrate, including a base substrate, and at least three functional layers, at least two first adaptation layers and a target connection member arranged on the base substrate. At least two functional layers of the at least three functional layers are laminated one on another in a direction away from the base substrate, the at least three functional layers include a target functional layer, and the target functional layer is a functional layer of the at least three functional layers furthest away from the base substrate. The at least two first adaptation layers include a top adaptation layer and at least one bottom adaptation layer, the top adaptation layer is arranged at a side of the target functional layer away from the base substrate and coupled to the target connection member and the target functional layer, and at least a part of the bottom adaptation layer is arranged between the target functional layer and the base substrate and coupled to the target functional layer and at least one non-target functional layer of the at least three functional layers.

In a possible embodiment of the present disclosure, the at least three functional layers further include a first functional layer and a second functional layer, at least a part of the first functional layer is arranged between the base substrate and the second functional layer, the at least two first adaptation layers include one of the bottom adaptation layers, and the bottom adaptation layer is coupled to the first functional layer and the second functional layer.

In a possible embodiment of the present disclosure, the first functional layer includes a protrusion, and an orthogonal projection of the protrusion onto the base substrate does not overlap with an orthogonal projection of the second functional layer onto the base substrate. The display substrate includes a first hole set, the bottom adaptation layer is coupled to the first functional layer and the second functional layer through the first hole set, and the target functional layer is directly lapped onto a portion of the bottom adaptation layer outside the first hole set.

In a possible embodiment of the present disclosure, the first hole set includes a first secondary through hole and a second secondary through hole in communication with each other, the first secondary through hole is arranged between the second secondary through hole and the base substrate, an aperture size of the second secondary through hole is greater than an aperture size of the first secondary through hole, the bottom adaptation layer is coupled to the second functional layer through the second secondary through hole, and the bottom adaptation layer is coupled to the first functional layer through the second secondary through hole and the first secondary through hole.

In a possible embodiment of the present disclosure, the target functional layer includes a first secondary target functional layer and a second secondary target functional layer laminated one on another, the first secondary target functional layer is arranged between the second secondary target functional layer and the base substrate, carrier mobility of the first secondary target functional layer is greater than carrier mobility of the second secondary target functional layer, and the first secondary target functional layer is directly lapped onto a portion of the bottom adaptation layer outside the first hole set.

In a possible embodiment of the present disclosure, the top adaptation layer is further directly coupled to the bottom adaptation layer.

In a possible embodiment of the present disclosure, the display substrate further includes a second hole set, the second hole set includes a third secondary through hole and a fourth secondary through hole in communication with each other, the third secondary through hole is arranged between the fourth secondary through hole and the base substrate, an aperture size of the fourth secondary through hole is greater than an aperture size of the third secondary through hole, the top adaptation layer is coupled to the target functional layer through the fourth secondary through hole, and the top adaptation layer is coupled to the bottom adaptation layer through the fourth secondary through hole and the third secondary through hole.

In a possible embodiment of the present disclosure, the display substrate includes a first source/drain metal layer, and the top adaptation layer is arranged at a same layer, and made of a same material, as the first source/drain metal layer.

In a possible embodiment of the present disclosure, the display substrate includes a plurality of sub-pixels arranged on the base substrate, each sub-pixel includes a sub-pixel driving circuitry and a light-emitting element, the sub-pixel driving circuitry includes a driving transistor, a sensing transistor and a storage capacitor, a first plate of the storage capacitor is coupled to a gate electrode of the driving transistor, and a second plate of the storage capacitor is coupled to a second electrode of the driving transistor, a second electrode of the sensing transistor and an anode of the light-emitting element. The first functional layer includes an active layer in the driving transistor, the second functional layer includes the second plate of the storage capacitor, the target functional layer includes a sensing active layer in the sensing transistor, and the target connection member includes the anode of the light-emitting element.

In a possible embodiment of the present disclosure, in the case that the target functional layer includes the first secondary target functional layer and the second secondary target functional layer laminated one on another, both the first secondary target functional layer and the second secondary target functional layer are made of a transparent metal oxide material.

In a possible embodiment of the present disclosure, the display substrate further includes a data line, the sub-pixel driving circuitry further includes a data write-in transistor, a first electrode of the data write-in transistor is coupled to a corresponding data line, and a second electrode of the data write-in transistor is coupled to the gate electrode of the driving transistor. The data write-in transistor includes a data write-in active layer, and the data line is arranged at a side of the data write-in active layer facing the base substrate.

In a possible embodiment of the present disclosure, the display substrate further includes a light-shielding layer arranged at a side of the data line facing the base substrate.

In a possible embodiment of the present disclosure, the display substrate further includes a sensing signal line, a second adaptation layer and a compensation signal line, a first electrode of the sensing transistor is coupled to a corresponding sensing signal line, the sensing signal line is coupled to a corresponding compensation signal line through a corresponding second adaptation layer, the compensation signal line is arranged at a same layer, and made of a same material, as the light-shielding layer, and at least a part of the second adaptation layer is arranged between the sensing signal line and the compensation signal line.

In a possible embodiment of the present disclosure, the display substrate further includes a light-shielding layer, and the data line is arranged at a side of the light-shielding layer facing the base substrate.

In a possible embodiment of the present disclosure, the display substrate further includes a light-shielding layer, and the data line is arranged at a same layer, and made of a same material, as the light-shielding layer.

In a possible embodiment of the present disclosure, the display substrate further includes a second gate metal layer, the sub-pixel driving circuitry further includes a third adaptation layer, the third adaptation layer is coupled to a portion of the data write-in active layer as the first electrode of the data write-in transistor and the data line, and the third adaptation layer is arranged at a same layer, and made of a same material, as the second gate metal layer.

In a possible embodiment of the present disclosure, the display substrate further includes a fourth adaptation layer, the fourth adaptation layer is coupled to a portion of the data write-in active layer as the second electrode of the data write-in transistor and the gate electrode of the driving transistor, and the fourth adaptation layer is arranged at a same layer, and made of a same material, as the bottom adaptation layer.

In a possible embodiment of the present disclosure, the display substrate further includes a third gate insulation layer, the sensing active layer includes a sensing channel portion and a sensing conductor portion, the sensing conductor portion is used as the first electrode and the second electrode of the sensing transistor, at least a part of the third gate insulation layer is arranged between a gate electrode of the sensing transistor and the sensing channel portion, and an orthogonal projection of the third gate insulation layer onto the base substrate does not overlap with an orthogonal projection of the sensing conductor portion onto the base substrate.

In a possible embodiment of the present disclosure, the display substrate further includes a third gate insulation layer, the sensing active layer includes a sensing channel portion and a sensing conductor portion, the sensing conductor portion is used as the first electrode and the second electrode of the sensing transistor, at least a part of the third gate insulation layer is arranged between a gate electrode of the sensing transistor and the sensing channel portion, and an orthogonal projection of the third gate insulation layer onto the base substrate covers an orthogonal projection of the sensing conductor portion onto the base substrate.

In another aspect, the present disclosure provides in some embodiments a display device including the above-mentioned display substrate.

### BRIEF DESCRIPTION OF THE DRAWINGS

The following drawings are provided to facilitate the understanding of the present disclosure, and constitute a portion of the description. These drawings and the following embodiments are for illustrative purposes only, but shall not be construed as limiting the present disclosure. In these drawings:

FIG. 1 is a circuit diagram of a sub-pixel driving circuitry according to one embodiment of the present disclosure;

FIG. 2 is a sequence diagram of the sub-pixel driving circuitry according to one embodiment of the present disclosure;

FIG. 3 is a sectional view of a display substrate according to one embodiment of the present disclosure;

FIG. 4 is another sectional view of the display substrate according to one embodiment of the present disclosure;

FIG. 5 is a schematic view showing a situation where an oxide active layer is coupled to a first source/drain metal layer according to one embodiment of the present disclosure;

FIG. 6 is an enlarged view of top and bottom adaptation layers in FIG. 4;

FIG. 7 is yet another sectional view of the display substrate according to one embodiment of the present disclosure;

FIG. 8 is still yet another sectional view of the display substrate according to one embodiment of the present disclosure;

FIG. 9 is an enlarged view of the top and bottom adaptation layers in FIG. 8;

FIG. 10 is still yet another sectional view of the display substrate according to one embodiment of the present disclosure;

FIG. 11 to FIG. 15 are schematic views showing the manufacture of the display substrate according to one embodiment of the present disclosure; and

FIG. 16 is still yet another sectional view of the display substrate according to one embodiment of the present disclosure.

### DETAILED DESCRIPTION

The present disclosure will be described hereinafter in conjunction with the drawings and embodiments.

Based on the analysis in the background art, there is an urgent need to optimize the layout design and the process, so as to reduce the density of the metal lines or reduce the quantity of through holes, thereby to improve the resolution of the display product while reducing the difficulty in the layout. In order to achieve the objects, the present disclosure provides the following technical solutions.

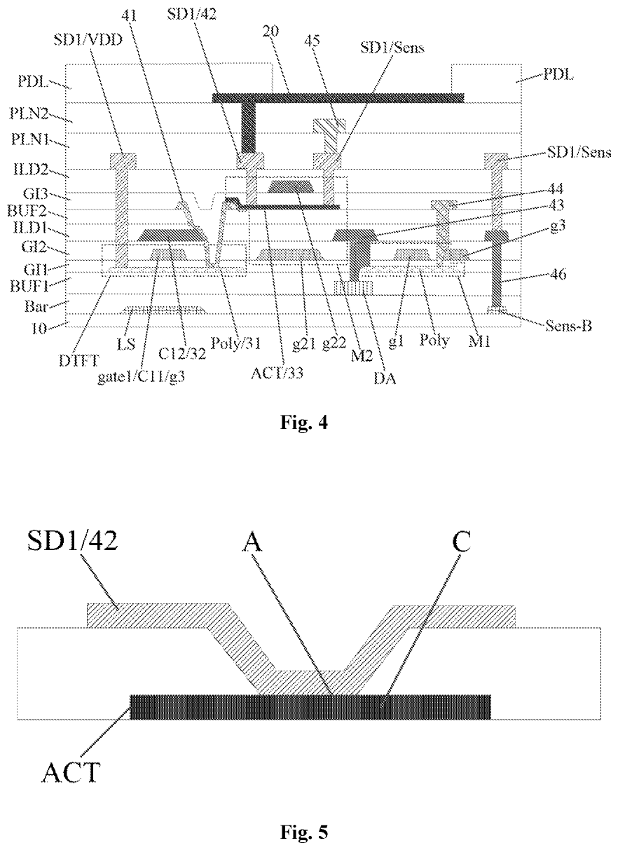

Referring to FIG. 4, the present disclosure provides in some embodiments a display substrate, which includes a base substrate 10, and at least three functional layers, at least two first adaptation layers and a target connection member 20 all arranged on the base substrate 10. At least two functional layers of the at least three functional layers are laminated one on another in a direction away from the base substrate 10, the at least three functional layers include a target functional layer 33, and the target functional layer 33 is a functional layer of the at least three functional layers furthest away from the base substrate 10. The at least two first adaptation layers include a top adaptation layer 42 and at least one bottom adaptation layer 41. The top adaptation layer 42 is arranged at a side of the target functional layer 33 away from the base substrate 10, and the top adaptation layer 42 is coupled to the target connection member 20 and the target functional layer 33. At least a part of the bottom adaptation layer 41 is arranged between the target functional layer 33 and the base substrate 10, and the bottom adaptation layer 41 is coupled to the target functional layer 33 and at least one non-target functional layer of the at least three functional layers (such as the first functional layer 31 and the second functional layer 32).

Illustratively, the display substrate includes a display region and a peripheral region surrounding the display region. The display region includes a plurality of sub-pixels arranged in an array form and a plurality of signal lines of different types, and the peripheral region includes a gate driving circuitry and a plurality of signal lines of different types. The peripheral region may also include any other circuitry structures. Alternatively, the peripheral region may not include any gate driving circuitry.

Illustratively, the display region includes the at least three functional layers, the at least two first adaptation layers, and the target connection member 20; and/or the peripheral region includes the at least three functional layers, the at least two first adaptation layers and the target connection member 20.

Illustratively, the at least three functional layers are laminated one on another in a direction away from the base substrate 10, and an insulation layer is arranged between the adjacent functional layers. Illustratively, orthogonal projections of any two functional layers onto the base substrate 10 overlap with each other, or do not overlap with each other.

Illustratively, the target connection member 20 is arranged at, but not limited to, a side of the top adaptation layer 42 away from the base substrate 10.

Illustratively, the non-target functional layer includes any film layer of the at least three functional layers other than the target functional layer 33.

Illustratively, the bottom adaptation layer 41 is coupled to the target functional layer 33 and the non-target functional layers of the at least three functional layers.

Based on the above-mentioned specific structure of the display substrate, the target functional layer 33 is coupled to the non-target functional layer through the bottom adaptation layer 41, and then the target functional layer 33 is coupled to the target connection member 20 through the top adaptation layer 42, so all the functional layers are coupled to the target connection member 20 through the top adaptation layer 42. The top adaptation layer 42 only needs to be coupled to the target functional layer 33 of the functional layers, so the top adaptation layer 42 only covers through holes between the top adaptation layer 42 and the target functional layer 33. As a result, it is able to reduce the quantity of through holes between the top adaptation layer 42 and the functional layers, and reduce an area of the top adaptation layer 42, thereby to improve the resolution of the display product while reducing the layout difficulty of the display substrate.

More specifically, as shown in FIG. 3, another connection mode is provided. In FIG. 3, only one top adaptation layer 42 is provided and coupled to various functional layers. At this time, the top adaptation layer 42 has a relatively large area, and it covers the through holes between the top adaptation layer 42 and each functional layer at the same time. However, in the embodiments of the present disclosure, the area of the top adaptation layer 42 in the display substrate is reduced significantly, so it is able to reduce the layout difficulty of the top adaptation layer 42 and improve the resolution of the display substrate.

As shown in FIG. 4, in some embodiments of the present disclosure, the at least three functional layers further include a first functional layer 31 and a second functional layer 32. At least a part of the first functional layer 31 is arranged between the base substrate 10 and the second functional layer 32, and the at least two first adaptation layers include one bottom adaptation layer 41 coupled to the first functional layer 31 and the second functional layer 32.

Illustratively, an orthogonal projection of the first functional layer 31 onto the base substrate 10 at least partially overlaps with an orthogonal projection of the second functional layer 32 onto the base substrate 10.

In the embodiments of the present disclosure, the target functional layer 33, the first functional layer 31 and the second functional layer 32 are coupled to each other through the bottom adaptation layer 41, and then the target functional layer 33 is coupled to the target connection member 20 through the top adaptation layer 42, so all the functional layers are coupled to the target connection member 20 through the top adaptation layer 42. The top adaptation layer 42 only needs to be coupled to the target functional layer 33 of the functional layers, so the top adaptation layer 42 only covers the through holes between the top adaptation layer 42 and the target functional layer 33. As a result, it is able to reduce the quantity of through holes between the top adaptation layer 42 and the functional layers, and reduce the area of the top adaptation layer 42, thereby to improve the resolution of the display product while reducing the layout difficulty of the display substrate.

As shown in FIG. 4, in some embodiments of the present disclosure, the first functional layer 31 includes a protrusion, and an orthogonal projection of the protrusion onto the base substrate 10 does not overlap with an orthogonal projection of the second functional layer 32 onto the base substrate 10. The display substrate includes a first hole set, and the bottom adaptation layer 41 is coupled to the first functional layer 31 and the second functional layer 32 through the first hole set. The target functional layer 33 is directly lapped onto a portion of the bottom adaptation layer 41 outside the first hole set.

Illustratively, in a direction parallel to the base substrate 10, the protrusion protrudes from the second functional layer 32, without being covered by the second functional layer 32.

Illustratively, the first hole set includes a first secondary through hole and a second secondary through hole in communication with each other, the first secondary through hole is arranged between the second secondary through hole and the base substrate 10, an aperture size of the second secondary through hole is greater than an aperture size of the first secondary through hole, the bottom adaptation layer 41 is coupled to the second functional layer 32 through the second secondary through hole, and the bottom adaptation layer 41 is coupled to the first functional layer 31 through the second secondary through hole and the first secondary through hole.

Illustratively, the first secondary through hole extends through an insulation layer between the first functional layer 31 and the second functional layer 32, and an insulation layer immediately adjacent to and covering the second functional layer 32. The second secondary through hole extends through an insulation layer between the target functional layer 33 and the second functional layer 32.

In the embodiments of the present disclosure, the bottom adaptation layer 41 is coupled to the first functional layer 31 and the second functional layer 32 through the first hole set, and the target functional layer 33 is directly lapped onto a portion of the bottom adaptation layer 41 outside the first hole set. Through optimizing the specific connection mode between the bottom adaptation layer 41 and each of the first functional layer 31, the second functional layer 32 and the target functional layer 33, it is able to reduce the connection complexity and increase the resolution of the display product. At the same time, the top adaptation layer 42 only needs to be coupled to the target functional layer 33 of the functional layer, so the top adaptation layer 42 only covers the through hole between the top adaptation layer 42 and the target functional layer 33. As a result, it is able to reduce the quantity of through holes between the top adaptation layer 42 and the functional layer, and reduce the area of the top adaptation layer 42, thereby to improve the resolution of the display product while reducing the layout difficulty of the display substrate.

As shown in FIG. 7, in some embodiments of the present disclosure, the target functional layer 33 includes a first secondary target functional layer 331 and a second secondary target functional layer 332 laminated one on another, the first secondary target functional layer 331 is arranged between the second secondary target functional layer 332 and the base substrate 10, and carrier mobility of the first secondary target functional layer 331 is greater than carrier mobility of the second secondary target functional layer 332. The first secondary target functional layer 331 is directly lapped onto a portion of the bottom adaptation layer 41 outside the first hole set.

Illustratively, the first secondary target functional layer 331 and the second secondary target functional layer 332 are each made of a transparent metal oxide. For example, the first secondary target functional layer 331 is made of, but not limited to, indium gallium zinc oxide (IGZO), and the second secondary target functional layer 332 is made of, but not limited to, indium gallium tin oxide (IGTO) or indium gallium zinc tin oxide (IGZYO).

When the target functional layer 33 includes a metal oxide active layer ACT (e.g., made of indium gallium zinc oxide (IGZO)) coupled to the metal layer, the metal oxide active layer ACT is arranged between the base substrate 10 and the metal layer, i.e., the metal oxide active layer ACT is arranged below the metal layer, and a surface of the metal oxide active layer ACT away from the base substrate 10 is in contact with the metal layer. A part of the metal oxide active layer ACT in contact with the metal layer needs to be treated to obtain form a conductor, so as to achieve well electrical connection. To be specific, the metal oxide active layer ACT is subjected to ion doping, plasma treatment, or diffusion of H ions.

As shown in FIG. 5, the metal oxide active layer ACT is located below the metal layer, and only an upper surface (indicated by A in FIG. 5) of the metal oxide active layer ACT needs to be treated to form a conductor, and an excellent electrical contact is formed between the metal oxide active layer ACT and the metal layer even if the doping ions fail to enter an intermediate layer (indicated by C in FIG. 5) of the metal oxide active layer ACT.

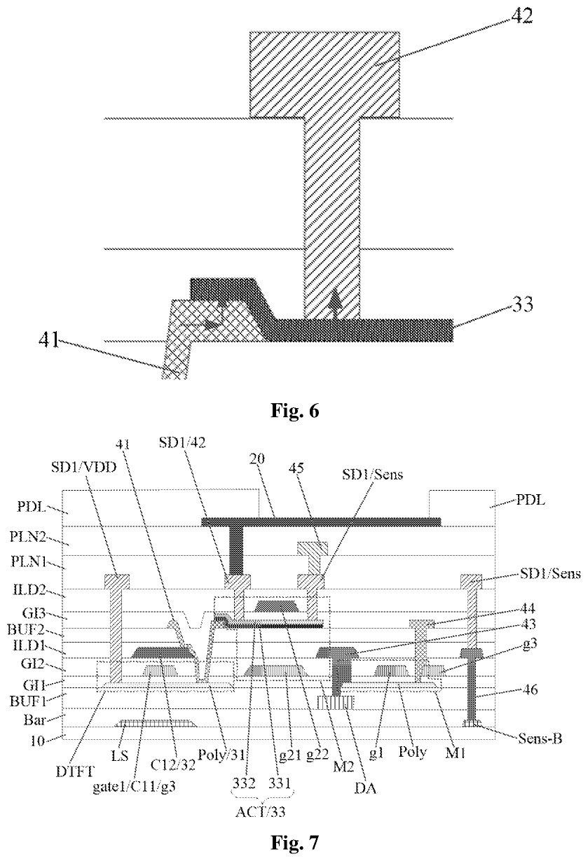

As shown in FIG. 6, an electrical connection is formed between the bottom adaptation layer 41 and a lower surface of the metal oxide active layer ACT, and then an electrical connection is formed between the top adaptation layer 42 and the upper surface of the metal oxide active layer ACT, so as to enable the top adaptation layer 42 to be coupled to the bottom adaptation layer 41. The lower surface of the metal oxide active layer ACT is treated to form a conductor having conductivity smaller than the upper surface of the metal oxide active layer ACT, i.e., there is a large contact resistance between the lower surface of the metal oxide active layer ACT and the bottom adaptation layer 41, so the connection performance between the top adaptation layer 42 and the bottom adaptation layer 41 may be adversely affected, and thereby the electrical connection between the top adaptation layer 42 and each of the first functional layer 31 and the second functional layer 32 may be adversely affected.

In the embodiments of the present disclosure, the carrier mobility of the first secondary target functional layer 331 is greater than the carrier mobility of the second secondary target functional layer 332, and the first secondary target functional layer 331 is directly lapped onto a portion of the bottom adaptation layer 41 outside the first hole set, so it is able to reduce the contact resistance between the target functional layer 33 and the bottom adaptation layer 41. In addition, the second secondary target functional layer 332 is selected as a top layer, so it is able to ensure the stability of the formed transistor structure.

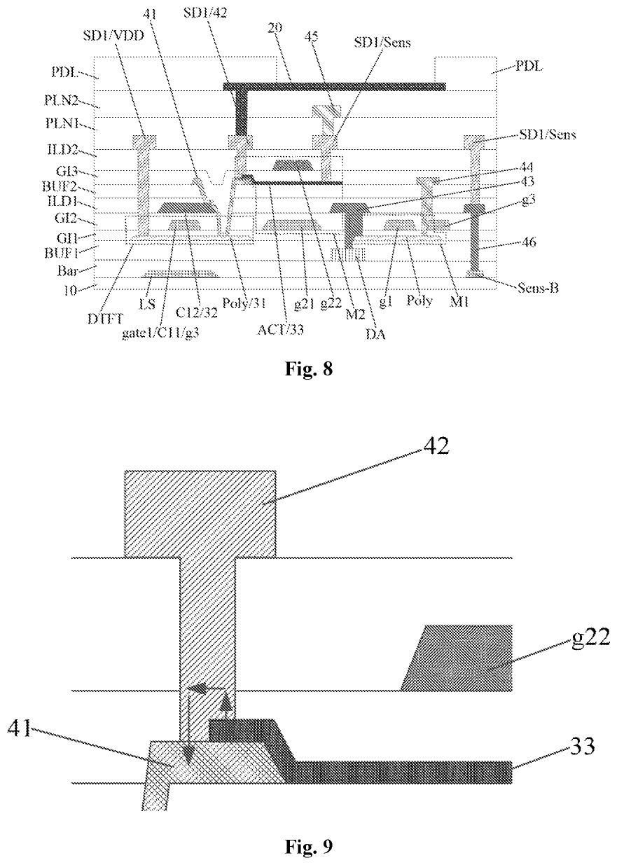

As shown in FIG. 8, in some embodiments of the present disclosure, the top adaptation layer 42 is also directly coupled to the bottom adaptation layer 41.

For example, the display substrate further includes a second hole set, the second hole set includes a third secondary through hole and a fourth secondary through hole in communication with each other, the third secondary through hole is arranged between the fourth secondary through hole and the base substrate 10, an aperture size of the fourth secondary through hole is greater than an aperture size of the third secondary through hole, the top adaptation layer 42 is coupled to the target functional layer 33 through the fourth secondary through hole, and the top adaptation layer 42 is coupled to the bottom adaptation layer 41 through the fourth secondary through hole and the third secondary through hole.

Illustratively, the third secondary through hole extends through an insulation layer covering and arranged immediately close to the target functional layer 33. The fourth secondary through hole extends through an insulation layer between the top adaptation layer 42 and the target functional layer 33.

Illustratively, the top adaptation layer 42 is directly lapped onto a portion of the bottom adaptation layer 41 outside the first hole set.

Based on the above, the top adaptation layer 42 is further directly coupled to the bottom adaptation layer 41, so as to achieve the well electrical connection between the top adaptation layer 42 and the bottom adaptation layer 41. To be specific, the top adaptation layer 42 is electrically coupled to the target functional layer 33 through the top adaptation layer 42 and the upper surface of the target functional layer 33, and the top adaptation layer 42 is in direct contact with the bottom adaptation layer, so as to form the well electrical connection between the top adaptation layer 42 and each of the first functional layer 31 and the second functional layer 32, thereby to reduce a contact resistance between the lower surface of the target functional layer 33 and the bottom adaptation layer 41.

As shown in FIG. 8, in some embodiments of the present disclosure, the display substrate includes a first source/drain metal layer SD1, and the top adaptation layer 42 is arranged at a same layer, and made of a same material, as the first source/drain metal layer SD1.

In the case that the top adaptation layer 42 is arranged at a same layer, and made of a same material, as the first source/drain metal layer SD1, the area of the top adaptation layer 42 is significantly reduced, so it is able to reduce the layout difficulty of the first source/drain metal layer SD1.

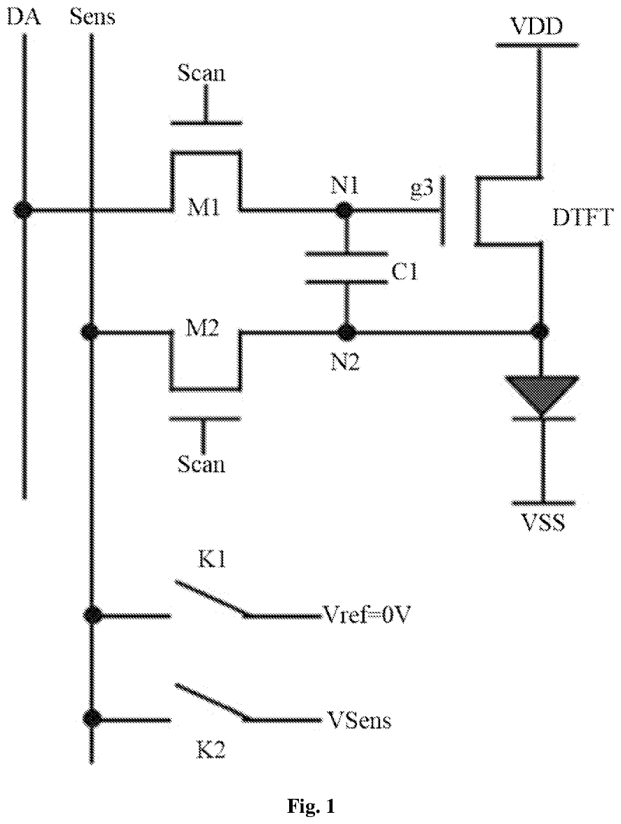

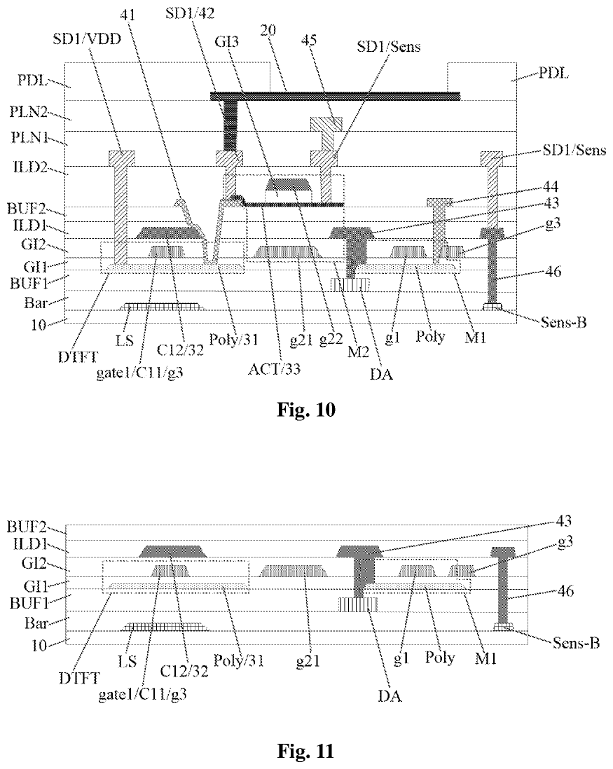

As shown in FIGS. 1 and 4-10, in some embodiments of the present disclosure, the display substrate includes a plurality of sub-pixels arranged on the base substrate 10, each sub-pixel includes a sub-pixel driving circuitry and a light-emitting element, and the sub-pixel driving circuitry includes a driving transistor DTFT, a sensing transistor M2 and a storage capacitor C1. A first plate C11 of the storage capacitor C1 is coupled to a gate electrode g3 of the driving transistor DTFT, and a second plate C12 of the storage capacitor C1 is respectively coupled to a second electrode of the driving transistor DTFT, a second electrode of the sensing transistor M2 and an anode of the light-emitting element.

The first functional layer 31 includes an active layer in the driving transistor DTFT, the second functional layer 32 includes the second plate C12 of the storage capacitor C1, the target functional layer 33 includes a sensing active layer in the sensing transistor M2, and the target connection member 20 includes the anode of the light-emitting element.

Illustratively, the display substrate includes a plurality of sub-pixels, and a plurality of sub-pixel driving circuitries in the plurality of sub-pixels is arranged in an array form, i.e., arranged in rows and columns. The plurality of rows of sub-pixel driving circuitries is arranged in a second direction, and each row includes a plurality of sub-pixel driving circuitries arranged in a first direction. The plurality of columns of sub-pixel driving circuitries is arranged in the first direction, and each column includes a plurality of sub-pixel driving circuitries arranged in the second direction. Illustratively, the first direction intersects the second direction. For example, the first direction includes a horizontal direction and the second direction includes a longitudinal direction.

Illustratively, the sub-pixel includes a sub-pixel driving circuitry and a light-emitting element. The sub-pixel driving circuitry is coupled to an anode of the light-emitting element, and configured to apply a driving signal to the light-emitting element so as to drive the light-emitting element to emit light.

Illustratively, the display substrate further includes a plurality of power supply lines VDD, a plurality of data lines DA, a plurality of sensing signal lines Sens, and a plurality of scanning lines Scan. The sub-pixel driving circuitry includes a driving transistor DTFT, a data write-in transistor M1, a sensing transistor M2 and a storage capacitor C1.

A gate electrode g3 of the driving transistor DTFT is coupled to a first plate C11 of the storage capacitor C1, a first electrode of the driving transistor DTFT is coupled to a corresponding power supply line VDD, and a second electrode of the driving transistor DTFT is coupled to an anode of the light-emitting element.

A gate electrode g1 of the data write-in transistor M1 is coupled to a corresponding scanning line Scan, a first electrode of the data write-in transistor M1 is coupled to a corresponding data line DA, and a second electrode of the data write-in transistor M1 is coupled to the gate electrode g3 of the driving transistor DTFT.

A gate electrode of the sensing transistor M2 is coupled to a corresponding scanning line Scan, a first electrode of the sensing transistor M2 is coupled to a corresponding sensing signal line Sens, a second electrode of the sensing transistor M2 is coupled to the anode of the light-emitting element, and a cathode of the light-emitting element is configured to receive a power supply signal VSS. Illustratively, the sensing transistor M2 includes a top gate electrode g22 and a bottom gate electrode g21.

As shown in FIG. 1, the sensing signal line Sens is coupled to a first signal end through a first switch K1 and coupled to a second signal end through a second switch K2, the first signal end is configured to provide a voltage signal of 0V, and the second signal end includes a sensing signal end VSens. The first signal end and the sensing signal end are both coupled to a driving chip in the display substrate. The first switch K1 is turned on or off under the control of a first control signal, and the second switch K2 is turned on or off under the control of a second control signal.

Illustratively, the sensing transistor M2 includes an oxide transistor, and the data write-in transistor M1 and the driving transistor DTFT include low temperature polysilicon transistors. The driving transistor DTFT, the data write-in transistor M1, and the sensing transistor M2 are, but not limited to, N-type transistors.

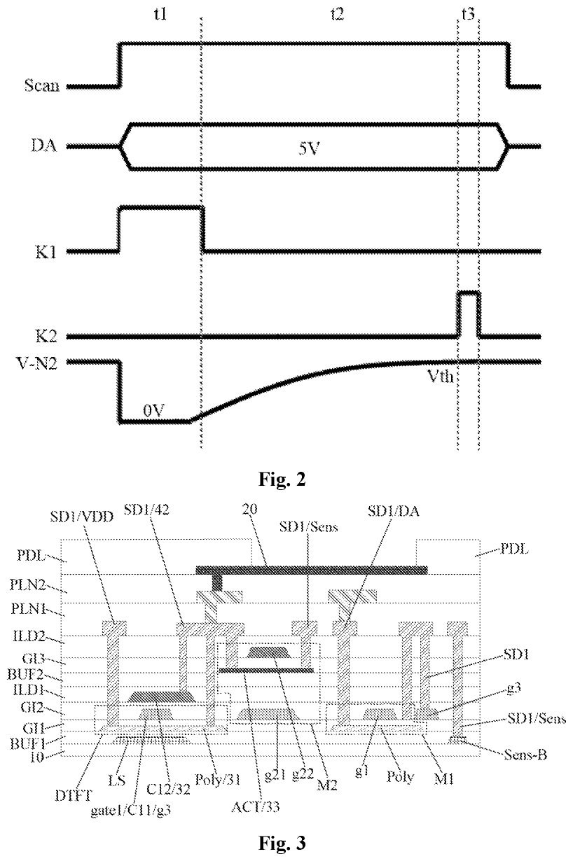

FIG. 2 is a sequence diagram of the sub-pixel driving circuitry. The first control signal, the second control signal and the scanning signal transmitted by the scanning line Scan are all active at a high level, i.e., in the case that the signal is at a high level, a corresponding switch is controlled to be turned on or a corresponding transistor is controlled to be turned on. A potential V-N2 at a node N2 is 0V at a starting phase and then gradually increases to a threshold voltage Vth of the driving transistor DTFT. A potential of a data signal transmitted by the data line DA is 5 V. In FIG. 2, the high level represents an active level for controlling the corresponding transistor to be turned on.

As shown in FIG. 2, there are three phases, a resetting phase t1, a compensation phase t2 and a sensing phase t3.

At the resetting phase t1, the first switch K1 is turned on, so as to turn on the data write-in transistor M1 and the sensing transistor M2, and reset the node N1 and a node N2. The potential V_N1 at the node N1 equal to Vdata, and Vdata is a voltage value of the data signal transmitted through the data line DA. A potential V_N2 at the node N2 is 0V.

At the compensation phase t2, a gate-to-source voltage Vgs of the driving transistor DTFT=Vdata−Vref>Vth, so the driving transistor DTFT is turned on, and the node N2 is charged by the power line VDD continuously through the driving transistor DTFT. Along with an increase in the potential at the node N2, Vgs decreases, and a turn-on degree of the driving transistor DTFT gradually decreases. When a difference between a source voltage Vs and a gate voltage Vg of the driving transistor is Vth, the driving transistor DTFT is completely turned off. At this time, V_N1=Vdata, and V_N2=Vdata−Vth.

At the sensing phase t3, the second switch K2 is turned on, and the sensing signal line Sens reads a voltage Vdata-Vth. The driving IC extracts Vdata-Vth and outputs it to a Field Programmable Gate Array (FPGA). The FPGA outputs a compensation value obtained using an algorithm to the driving IC, so that the driving IC compensates for the data signal with the compensation value.

In order to achieve a high resolution, when the three transistors are all low-temperature polysilicon transistors, a large space needs to be occupied. When two transistors are oxide transistors and one transistor is a low-temperature polysilicon transistor, the display substrate may have a large thickness, and it is not easy to realize cross-line connection, so the yield of the display product may be adversely affected. Hence, in the embodiments of the present disclosure, the sub-pixel driving circuitry includes one oxide transistor and two low-temperature polysilicon transistors, so as to solve the above-mentioned problems and improve the resolution of the display product.

More detailedly, as shown in FIG. 3, when the resolution of the display product gradually increases, a size of an individual sub-pixel gradually decreases, so the layout of the first source/drain metal layer SD1 in the display substrate becomes more complicated. The first source/drain metal layer SD1 is used to form a plurality of signal lines independent of each other, as well as adaptation layers. For example, the signal lines include the power line VDD, the sensing signal line Sens, the data line DA, etc. The adaptation layers include the top adaptation layer 42 and any other adaptation layers. Along with an increase in the resolution, there is insufficient space for the lines. When a line width or line spacing is reduced, such a problem as short circuit or open circuit may occur, and thereby the improvement in the resolution of the display product may be adversely affected.

In the embodiments of the present disclosure, the first functional layer 31 includes the active layer of the driving transistor DTFT, the second functional layer 32 includes the second plate C12 of the storage capacitor C1, the target functional layer 33 includes the sensing active layer of the sensing transistor M2, and the target connection member 20 includes the anode of the light-emitting element. Illustratively, the active layer of the driving transistor DTFT includes a polysilicon active layer Poly and the sense active layer in the sensing transistor M2 includes a metal oxide active layer ACT.

In the embodiments of the present disclosure, the first source/drain metal layer SD1 includes the top adaptation layer 42. The active layer of the driving transistor DTFT, the second plate C12 of the storage capacitor C1 and the sensing active layer of the sensing transistor M2 are coupled to each other through the bottom adaptation layer 41, so the top adaptation layer 42 only needs to be coupled to the sensing active layer and/or the bottom adaptation layer 41, so as to reduce the quantity of through holes when the top adaptation layer 42 is coupled to a bottom film layer, thereby to reduce the quantity of through holes to be covered by the top adaptation layer 42. In this way, it is able to reduce an area or size of the top adaptation layer 42, reduce an area or size of the first source/drain metal layer SD1, and facilitate the layout of the first source/drain metal layer SD1, thereby to further improve the resolution of the high-resolution display product.

Furthermore, in the case that the top adaptation layer 42 is directly coupled to both the sensing active layer and the bottom adaptation layer 41, it is able to reduce a contact resistance when the sensing active layer is lapped onto the bottom adaptation layer 41, thereby to improve a display effect of the display product. In addition, it is able to improve the conductivity between the top adaptation layer 42 and the bottom adaptation layer 41, and reduce the loading, thereby to improve the display uniformity.

As shown in FIG. 7, in some embodiments of the present disclosure, in the case that the target functional layer 33 includes the first secondary target functional layer 331 and the second secondary target functional layer 332 laminated one on another, both the first secondary target functional layer 331 and the second secondary target functional layer 332 are made of a transparent metal oxide material.

Illustratively, the sensing active layer includes the first secondary target functional layer 331 and the second secondary target functional layer 332 laminated one on another.

The carrier mobility of the first secondary target functional layer 331 is greater than the carrier mobility of the second secondary target functional layer 332, and the first secondary target functional layer 331 is directly lapped onto a portion of the bottom adaptation layer 41 outside the first hole set, so it is able to reduce a contact resistance between the target functional layer 33 and the bottom adaptation layer 41, and reduce the contact resistance when the target functional layer 33 is lapped onto the bottom adaptation layer 41. In addition, when the second sub-target function layer 332 serves as a top layer, it is able to ensure the stable characteristics of the sensing transistor M2.

As shown in FIGS. 4, 7, 8 and 10, in some embodiments of the present disclosure, the display substrate further includes a data line DA. The sub-pixel driving circuitry further includes a data write-in transistor M1, a first electrode of the data write-in transistor M1 is coupled to a corresponding data line DA, and a second electrode of the data write-in transistor M1 is coupled to the gate electrode g3 of the driving transistor DTFT. The data write-in transistor M1 includes a data write-in active layer, and the data line DA is arranged at a side of the data write-in active layer facing the base substrate 10.

It should be appreciated that, in FIGS. 4, 7, 8 and 10, g3 is shown at a right side, and it may be a structure coupled to the gate electrode g3 of the driving transistor DTFT, i.e., it may be at a same potential as the gate electrode g3 of the driving transistor DTFT, and it may not serve as the gate electrode g3 of the driving transistor DTFT.

Illustratively, the data write-in active layer includes a polysilicon active layer Poly.

More detailedly, as shown in FIG. 3, in the case that the first source/drain metal layer SD1 is used to form a plurality of signal lines independent of each other and some adaptation layers, different signals need to be transmitted between the signal lines and the adaptation patterns, so short circuit needs to be prevented, i.e. it is necessary to ensure a certain spacing therebetween. However, due to the high resolution, a layout space of the first source/drain metal layer SD1 is limited, and thereby it is difficult to increase the resolution.

In the embodiments of the present disclosure, the data line DA is arranged at a side of the data write-in active layer facing the base substrate 10, and the data line DA originally formed using the first source/drain metal layer SD1 is formed at a bottom layer of the display substrate, so as to reduce the complexity of the first source/drain metal layer SD1, and reduce the layout difficulty of the first source/drain metal layer SD1, thereby to further increase the resolution of the high-resolution display product.

In the embodiments of the present disclosure, when the data line DA is arranged at a layer different from the first source/drain metal layer SD1, i.e., when the data line DA is arranged above or below the first source/drain metal layer SD1, it is able to reduce the layout difficulty of the first source/drain metal layer SD1, thereby to further increase the resolution of the high-resolution display product.

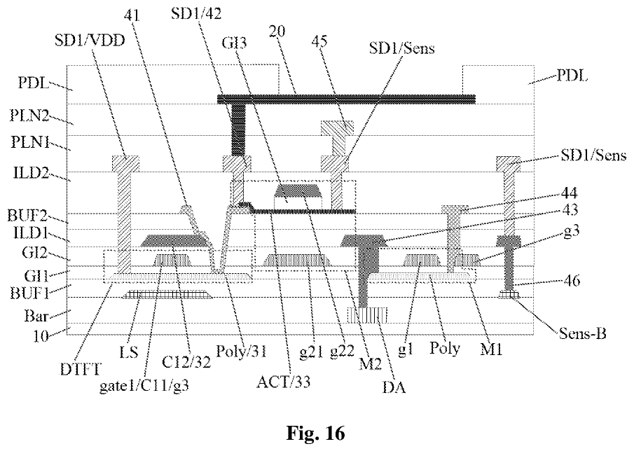

In some embodiments of the present disclosure, the display substrate further includes a light-shielding layer LS. As shown in FIGS. 4, 7, 8 and 10, the light-shielding layer LS is arranged at a side of the data line DA facing the base substrate 10; or as shown in FIG. 16, the data line DA is arranged at a side of the light-shielding layer LS facing the base substrate 10; or the data line DA is arranged at a same layer, and made of a same material, as the light-shielding layer LS.

When the light-shielding layer LS and the data line DA are arranged at different layers, it is able to provide a large layout space for both the light-shielding layer LS and the data line DA, thereby to reduce the layout difficulty of the display substrate. When data line DA is arranged at a same layer, and made of a same material, as the light-shielding layer LS, it is able to form the data line DA and the light-shielding layer LS through a single patterning process, thereby to simplify the manufacture of the display substrate and reduce the manufacture cost thereof.

When the data line DA is arranged at a side of the light-shielding layer LS facing the base substrate 10, it is able to further reduce a parasitic capacitance generated between the data line DA and a peripheral structure, e.g., a parasitic capacitance generated between the data line and the gate electrode of the data write-in transistor. It should be appreciated that, an isolation layer Bar is also illustrated in FIG. 16.

As shown in FIGS. 4, 7, 8 and 10, in some embodiments of the present disclosure, the display substrate further includes a sensing signal line Sens, a second adaptation layer 46, and a compensation signal line Sens-B. The first electrode of the sensing transistor M2 is coupled to a corresponding sensing signal line Sens, and the sensing signal line Sens is coupled to a corresponding compensation signal line Sens-B through a corresponding second adaptation layer 46. The compensation signal line Sens-B is arranged at a same layer, and made of a same material, as the light-shielding layer LS, and at least a part of the second adaptation layer 46 is arranged between the sensing signal line Sens and the compensation signal line Sens-B.

Illustratively, the display substrate includes a second gate metal layer, and the second adaptation layer 46 is arranged at a same layer, and made of a same material, as the second gate metal layer.

When the compensation signal line Sens-B is arranged at a same layer, and made of a same material, as the light-shielding layer LS, it is able to form the compensation signal line Sens-B and the light-shielding layer LS through a single patterning process, thereby to simplify the manufacture of the display substrate and reduce the manufacture cost thereof.

When at least a part of the second adaptation layer 46 is arranged between the sensing signal line Sens and the compensation signal line Sens-B, the second adaptation layer 46 serves as an adapter between the corresponding sensing signal line Sens and the compensation signal line Sens-B, so it is able to ensure the connection performance between the sensing signal line Sens and the compensation signal line Sens-B, without any deep hole through which the compensation signal line Sens-B is directly coupled to the sensing signal line Sens, thereby to improve the yield of the display substrate.

As shown in FIGS. 4, 7, 8 and 10, in some embodiments of the present disclosure, the display substrate further includes a second gate metal layer, the sub-pixel driving circuitry further includes a third adaptation layer 43, and the third adaptation layer 43 is coupled to a portion of the data write-in active layer as the first electrode of the data write-in transistor M1 and the data line DA. The third adaptation layer 43 is arranged at a same layer, and made of a same material, as the second gate metal layer.

Based on the above, it is able to ensure the connection performance between the data write-in transistor M1 and the corresponding data line DA, and reduce the connection difficulty between the data write-in transistor M1 and the data line DA. In addition, when the third adaptation layer 43 is arranged at a same layer, and made of a same material, as the second gate metal layer, it is able to form the third adaptation layer 43 and the second gate metal layer through a single patterning process, thereby to simplify the manufacture of the display substrate and reduce the manufacture cost thereof.

As shown in FIGS. 4, 7, 8 and 10, in some embodiments of the present disclosure, the display substrate further includes a fourth adaptation layer 44 coupled to a part of the data write-in active layer as a second electrode of the data write-in transistor M1 and the gate electrode g3 of the driving transistor DTFT. The fourth adaptation layer 44 is arranged at a same layer, and made of a same material, as the bottom adaptation layer 41.

Based on the above, it is able to ensure the connection performance between the data write-in transistor M1 and the driving transistor DTFT, and reduce the connection difficulty between the data write-in transistor M1 and the driving transistor DTFT. In addition, when the fourth adaptation layer 44 is arranged at a same layer, and made of a same material, as the bottom adaptation layer 41, it is able to form the fourth adaptation layer 44 and the bottom adaptation layer 41 through a single patterning process, thereby to simplify the manufacture of the display substrate and reduce the manufacture cost thereof.

As shown in FIG. 10, in some embodiments of the present disclosure, the display substrate further includes a third gate insulation layer GI3, the sensing active layer includes a sensing channel portion and a sensing conductor portion, the sensing conductor portion serves as the first electrode and the second electrode of the sensing transistor M2, and at least a part of the third gate insulation layer GI3 is arranged between the gate electrode of the sensing transistor M2 and the sensing channel portion. An orthogonal projection of the third gate insulation layer GI3 onto the base substrate 10 does not overlap with an orthogonal projection of the sensing conductor portion onto the base substrate 10.

Illustratively, an orthogonal projection of the sensing channel portion onto the base substrate 10 overlaps with an orthogonal projection of the gate electrode of the sensing transistor M2 onto the base substrate 10, and the orthogonal projection of the sensing conductor portion onto the base substrate 10 does not overlap with the orthogonal projection of the gate electrode of the sensing transistor M2 onto the base substrate 10.

Illustratively, the gate electrode of the sensing transistor M2 is arranged at a side of the third gate insulation layer GI3 away from the base substrate 10.

In the embodiments of the present disclosure, when the orthogonal projection of the third gate insulation layer GI3 onto the base substrate 10 does not overlap with the orthogonal projection of the sensing conductor portion onto the base substrate 10, it is able to improve a conductor level of the sensing conductor portion, thereby to improve the connection performance between the target functional layer 33 and each of the top adaptation layer and the bottom adaptation layer.

As shown in FIGS. 4, 7 and 8, in some embodiments of the present disclosure, the display substrate further includes a third gate insulation layer GI3, the sensing active layer includes a sensing channel portion and a sensing conductor portion, the sensing conductor portion serves as the first electrode and the second electrode of the sensing transistor M2, and at least a part of the third gate insulation layer GI3 is arranged between the gate electrode of the sensing transistor M2 and the sensing channel portion. An orthogonal projection of the third gate insulation layer GI3 onto the base substrate 10 covers an orthogonal projection of the sensing conductor portion onto the base substrate 10.

Illustratively, the third gate insulation layer GI3 is an entire layer covering the base substrate 10.

As shown in FIGS. 4, 7, 8 and 10, in some embodiments of the present disclosure, the display substrate further includes a fifth adaptation layer 45 arranged at a side of the sensing signal line Sens away from the base substrate 10 and coupled to the sensing signal line Sens.

Illustratively, the fifth adaptation layer 45 is made of molybdenum (Mo), or it has a laminated structure made of titanium (Ti)/aluminum (Al)/titanium.

Through fifth adaptation layer 45, it is able for the sensing signal line Sens to be coupled to the other structures.

It should be appreciated that, the fifth adaptation layer 45 is arranged at a layer different from the first source/drain metal layer SD1, and arranged at a layer different from the anode of the light-emitting element. In the display substrate, through the fifth adaptation layer 45 arranged independently, it is able to couple the sensing signal line Sens to the other structures, and facilitate the layout of the first source/drain metal layer SD1 and the film layer where the anode is located.

The present disclosure further provides in some embodiments a method for manufacturing a display substrate, which will be described hereinafter.

As shown in FIG. 11, a light-shielding layer LS, a barrier layer, a first conductive layer (for forming a data line DA), a first buffer layer BUF1, a polycrystalline silicon active layer Poly, a first gate insulation layer GI1, a first gate metal layer gate1, a second gate insulation layer GI2, a through hole through which the second gate metal layer is coupled to an underlying layer, a second gate metal layer, a first interlayer insulation layer ILD1 and a second buffer layer BUF2 are laminated one on another on the base substrate 10. In this way, the data line DA is arranged at a side of the polycrystalline silicon active layer Poly facing the base substrate 10, so as to facilitate the layout of the first source/drain metal layer SD1 in the case of a high resolution, thereby to further increase the resolution of a high-resolution display product.

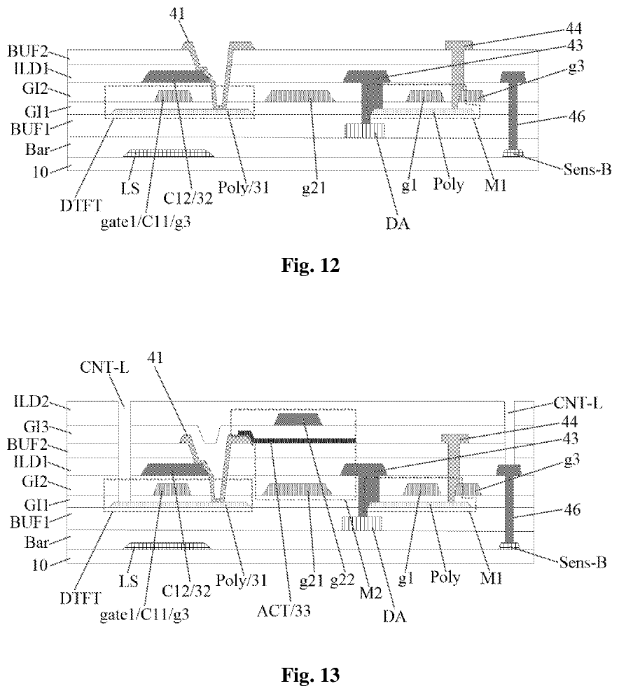

As shown in FIG. 12, the first hole set, the bottom adaptation layer 41 and the fourth adaptation layer 44 are formed. In this way, it is able to facilitate the layout of the first source/drain metal layer SD1 in the case of a high resolution, thereby to further increase the resolution of the high-resolution display product.

As shown in FIG. 13, a metal oxide active layer ACT, a third gate insulation layer GI3, a third gate metal layer, a second interlayer insulation layer ILD2 and a first connection hole CNT-L are formed.

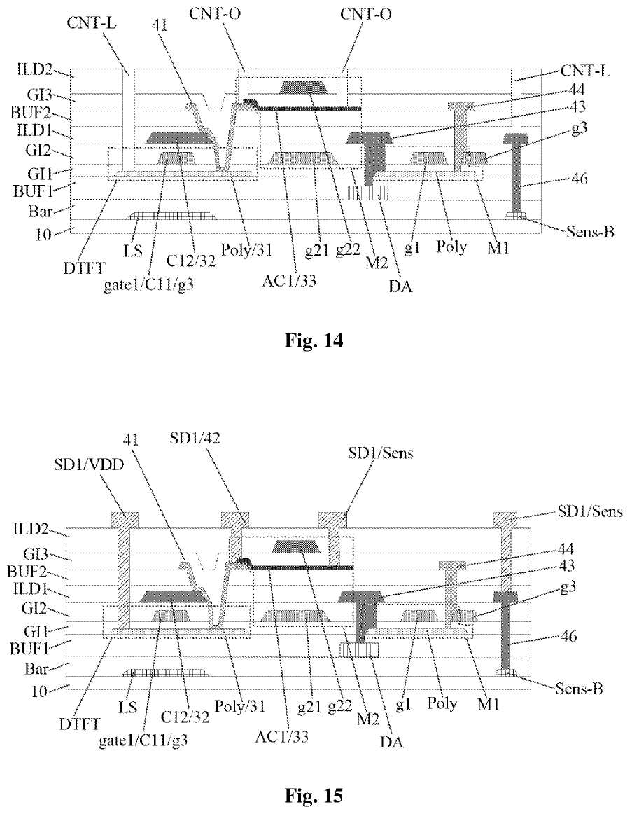

As shown in FIG. 14, a second connection hole CNT-O (including the second hole set) is formed.

As shown in FIG. 15, the first source/drain metal layer SD1 is formed.

As shown in FIG. 8, a first planarization layer PLN1, a fifth adaptation layer 45, a second planarization layer PLN2, an anode layer and a pixel definition layer PDL are formed. Subsequently, a light-emitting functional layer, a cathode layer and an encapsulation layer are formed, and these layers are not shown in the drawings.

The present disclosure further provides in some embodiments a display device which includes the above-mentioned display substrate.

It should be appreciated that, the display device may be any product or member having a display function, such as television, display, digital photo frame, mobile phone or tablet computer. The display device may further include a flexible circuit board, a printed circuit board and a back plate.

According to the display substrate in the embodiments of the present disclosure, the target functional layer 33 is coupled to the non-target functional layer through the bottom adaptation layer 41, and then the target functional layer 33 is coupled to the target connection member 20 through the top adaptation layer 42, so all the functional layers are coupled to the target connection member 20 through the top adaptation layer 42. The top adaptation layer 42 only needs to be coupled to the target functional layer 33 of the functional layers, so the top adaptation layer 42 only covers through holes between the top adaptation layer 42 and the target functional layer 33. As a result, it is able to reduce the quantity of through holes between the top adaptation layer 42 and the functional layers, and reduce an area of the top adaptation layer 42, thereby to improve the resolution of the display product while reducing the layout difficulty of the display substrate.

When the display device includes the above-mentioned display substrate, it also has the above-mentioned beneficial effects, which will not be particularly defined herein.

It should be appreciated that, the function of the second hole set is to couple the target functional layer 33 to the bottom adaptation layer 41 through the top adaptation layer 42, and a size or position of the second hole set may be appropriately selected to adjust a contact area between the top adaptation layer 42 and each of an upper surface of the target functional layer 33 and the bottom adaptation layer 41, so as to ensure the connection performance. The connection relationship between the top adaptation layer 42 and each of the upper surface of the target functional layer 33 and the bottom adaptation layer 41 has been described hereinabove, and any modification or improvement may be made without departing from the spirit of the present disclosure.

In the embodiments of the present disclosure, one first hole set and one second hole set are provided for each sub-pixel. However, more similar holes may be provided for each sub-pixel according to the practical need, so as to increase the resolution of the display product, i.e., any modification or improvement may be made without departing from the spirit of the present disclosure.

In the embodiments of the present disclosure, the target functional layer 33 may be a transparent metal oxide semiconductor active layer made of IGTO or IGZYO, or it may include two or more transparent metal oxide semiconductor active layers. The polycrystalline silicon active layer Poly may be replaced with an IGZO active layer. In other words, i.e., any modification or improvement may be made without departing from the spirit of the present disclosure.

In the embodiments of the present disclosure, a structure originally formed by the first source/drain metal layer SD1 (for example, the data line DA) moves upward or downward, i.e., the structure is arranged at a layer different from the first source/drain metal layer SD1, so as to facilitate the layout of the first source/drain metal layer SD1, thereby to further increase the resolution of the high-resolution display product. In other words, i.e., any modification or improvement may be made without departing from the spirit of the present disclosure.

It should be appreciated that, the expression “at a same layer” refers to that the film layers are arranged on a same structural layer. Alternatively, for example, the film layers on a same layer may be layer structures formed through forming thin layers for forming specific patterns through a single-film-forming process and then patterning the film layers with a same mask through a single patterning process. Depending on different specific patterns, a single patterning process may include multiple exposing, development or etching processes, and the specific patterns in the layer structure may be continuous or discontinuous. These specific patterns may also be arranged at different levels or have different thicknesses.

In the embodiments of the present disclosure, the order of the steps is not limited to the serial numbers thereof. For a person skilled in the art, any change in the order of the steps shall also fall within the scope of the present disclosure if without any creative effort.

It should be further appreciated that, the above embodiments have been described in a progressive manner, and the same or similar contents in the embodiments have not been repeated, i.e., each embodiment has merely focused on the difference from the others. Especially, the method embodiments are substantially similar to the product embodiments, and thus have been described in a simple manner.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “include” or “including” intends to indicate that an element or object before the word contains an element or object or equivalents thereof listed after the word, without excluding any other element or object. Such words as “connect/connected to” or “couple/coupled to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

It should be appreciated that, in the case that such an element as layer, film, region or substrate is arranged “on” or “under” another element, it may be directly arranged “on” or “under” the other element, or an intermediate element may be arranged therebetween.

In the above description, the features, structures, materials or characteristics may be combined in any embodiment or embodiments in an appropriate manner.

The above embodiments are for illustrative purposes only, but the present disclosure is not limited thereto. Obviously, a person skilled in the art may make further modifications and improvements without departing from the spirit of the present disclosure, and these modifications and improvements shall also fall within the scope of the present disclosure.

1. A display substrate, comprising a base substrate, and at least three functional layers, at least two first adaptation layers and a target connection member arranged on the base substrate, wherein at least two functional layers of the at least three functional layers are laminated one on another in a direction away from the base substrate, the at least three functional layers comprise a target functional layer, and the target functional layer is a functional layer of the at least three functional layers furthest away from the base substrate,
wherein the at least two first adaptation layers comprise a top adaptation layer and at least one bottom adaptation layer, the top adaptation layer is arranged at a side of the target functional layer away from the base substrate and coupled to the target connection member and the target functional layer, and at least a part of the bottom adaptation layer is arranged between the target functional layer and the base substrate and coupled to the target functional layer and at least one non-target functional layer of the at least three functional layers.

2. The display substrate according to claim 1, wherein the at least three functional layers further comprise a first functional layer and a second functional layer, at least a part of the first functional layer is arranged between the base substrate and the second functional layer, the at least two first adaptation layers comprise one of the bottom adaptation layers, and the bottom adaptation layer is coupled to the first functional layer and the second functional layer.

3. The display substrate according to claim 2, wherein the first functional layer comprises a protrusion, and an orthogonal projection of the protrusion onto the base substrate does not overlap with an orthogonal projection of the second functional layer onto the base substrate,
wherein the display substrate comprises a first hole set, the bottom adaptation layer is coupled to the first functional layer and the second functional layer through the first hole set, and the target functional layer is directly lapped onto a portion of the bottom adaptation layer outside the first hole set.

4. The display substrate according to claim 3, wherein the first hole set comprises a first secondary through hole and a second secondary through hole in communication with each other, the first secondary through hole is arranged between the second secondary through hole and the base substrate, an aperture size of the second secondary through hole is greater than an aperture size of the first secondary through hole, the bottom adaptation layer is coupled to the second functional layer through the second secondary through hole, and the bottom adaptation layer is coupled to the first functional layer through the second secondary through hole and the first secondary through hole.

5. The display substrate according to claim 3, wherein the target functional layer comprises a first secondary target functional layer and a second secondary target functional layer laminated one on another, the first secondary target functional layer is arranged between the second secondary target functional layer and the base substrate, carrier mobility of the first secondary target functional layer is greater than carrier mobility of the second secondary target functional layer, and the first secondary target functional layer is directly lapped onto a portion of the bottom adaptation layer outside the first hole set.

6. The display substrate according to claim 3, wherein the top adaptation layer is further directly coupled to the bottom adaptation layer.

7. The display substrate according to claim 6, further comprising a second hole set, wherein the second hole set comprises a third secondary through hole and a fourth secondary through hole in communication with each other, the third secondary through hole is arranged between the fourth secondary through hole and the base substrate, an aperture size of the fourth secondary through hole is greater than an aperture size of the third secondary through hole, the top adaptation layer is coupled to the target functional layer through the fourth secondary through hole, and the top adaptation layer is coupled to the bottom adaptation layer through the fourth secondary through hole and the third secondary through hole.

8. The display substrate according to claim 3, further comprising a first source/drain metal layer, wherein the top adaptation layer is arranged at a same layer, and made of a same material, as the first source/drain metal layer.

9. The display substrate according to claim 3, further comprising a plurality of sub-pixels arranged on the base substrate, wherein each sub-pixel comprises a sub-pixel driving circuitry and a light-emitting element, the sub-pixel driving circuitry comprises a driving transistor, a sensing transistor and a storage capacitor, a first plate of the storage capacitor is coupled to a gate electrode of the driving transistor, and a second plate of the storage capacitor is coupled to a second electrode of the driving transistor, a second electrode of the sensing transistor and an anode of the light-emitting element,
wherein the first functional layer comprises an active layer in the driving transistor, the second functional layer comprises the second plate of the storage capacitor, the target functional layer comprises a sensing active layer in the sensing transistor, and the target connection member comprises the anode of the light-emitting element.

10. The display substrate according to claim 9, wherein in the case that the target functional layer comprises the first secondary target functional layer and the second secondary target functional layer laminated one on another, both the first secondary target functional layer and the second secondary target functional layer are made of a transparent metal oxide material.

11. The display substrate according to claim 9, further comprising a data line, wherein the sub-pixel driving circuitry further comprises a data write-in transistor, a first electrode of the data write-in transistor is coupled to a corresponding data line, and a second electrode of the data write-in transistor is coupled to the gate electrode of the driving transistor,
wherein the data write-in transistor comprises a data write-in active layer, and the data line is arranged at a side of the data write-in active layer facing the base substrate.

12. The display substrate according to claim 11, further comprising a light-shielding layer arranged at a side of the data line facing the base substrate.

13. The display substrate according to claim 12, further comprising a sensing signal line, a second adaptation layer and a compensation signal line, wherein a first electrode of the sensing transistor is coupled to a corresponding sensing signal line, the sensing signal line is coupled to a corresponding compensation signal line through a corresponding second adaptation layer, the compensation signal line is arranged at a same layer, and made of a same material, as the light-shielding layer, and at least a part of the second adaptation layer is arranged between the sensing signal line and the compensation signal line.

14. The display substrate according to claim 11, further comprising a light-shielding layer, wherein the data line is arranged at a side of the light-shielding layer facing the base substrate.

15. The display substrate according to claim 11, further comprising a light-shielding layer, wherein the data line is arranged at a same layer, and made of a same material, as the light-shielding layer.

16. The display substrate according to claim 11, further comprising a second gate metal layer, wherein the sub-pixel driving circuitry further comprises a third adaptation layer, the third adaptation layer is coupled to a portion of the data write-in active layer as the first electrode of the data write-in transistor and the data line, and the third adaptation layer is arranged at a same layer, and made of a same material, as the second gate metal layer.

17. The display substrate according to claim 11, further comprising a fourth adaptation layer, wherein the fourth adaptation layer is coupled to a portion of the data write-in active layer as the second electrode of the data write-in transistor and the gate electrode of the driving transistor, and the fourth adaptation layer is arranged at a same layer, and made of a same material, as the bottom adaptation layer.

18. The display substrate according to claim 9, further comprising a third gate insulation layer, wherein the sensing active layer comprises a sensing channel portion and a sensing conductor portion, the sensing conductor portion is used as the first electrode and the second electrode of the sensing transistor, at least a part of the third gate insulation layer is arranged between a gate electrode of the sensing transistor and the sensing channel portion, and an orthogonal projection of the third gate insulation layer onto the base substrate does not overlap with an orthogonal projection of the sensing conductor portion onto the base substrate.

19. The display substrate according to claim 9, further comprising a third gate insulation layer, wherein the sensing active layer comprises a sensing channel portion and a sensing conductor portion, the sensing conductor portion is used as the first electrode and the second electrode of the sensing transistor, at least a part of the third gate insulation layer is arranged between a gate electrode of the sensing transistor and the sensing channel portion, and an orthogonal projection of the third gate insulation layer onto the base substrate covers an orthogonal projection of the sensing conductor portion onto the base substrate.

20. A display device, comprising the display substrate according to claim 1.
